(19) United States
(12) Patent Application Publication
(10) Pub. No.: US 2004/0102013 A1
(43) Pub. Date: May 27, 2004

(54) Codoping of source drains using carbon or fluorine ion implants to improve polysilicon depletion

(76) Inventors: Jack Hwang, Portland, OR (US); Mitchell Taylor, Lake Oswego, OR (US); Craig Andyke, Portland, OR (US); Mark Armstrong, Portland, OR (US); Jerry Zietz, Banks, OR (US); Harold Kennel, Beaverton, OR (US); Stephen Cea, Hillsboro, OR (US); Thomas Hoffman, Hillsboro, OR (US); Seok-Hee Lee, Portland, OR (US)

Correspondence Address: Timothy N. Trop, TROP, PRUNER & HU, P.C., STE 100, 8554 KATY FWY, HOUSTON, TX, 77024-1841, US

(21) Appl. No.: 10/306,320

(22) Filed: Nov. 27, 2002

(51) Int. Cl. H01L 21/331

(52) U.S. Cl. 438/313

(57) ABSTRACT

In accordance with some embodiments, codoping with carbon or fluorine and phosphorous may form NMOS source drain junctions with desirable short channel performance, improved drive current, and desirable polysilicon depletion. Thus, phosphorous doping levels may be increased, improving transistor performance without other significant adverse effects.

### BACKGROUND

This invention relates generally to the fabrication of integrated circuits.

In the fabrication of integrated circuits, commonly source drain junctions are formed using a gate and spacer structure as a mask. As lateral device dimensions have scaled, it is necessary to scale the vertical junction depth to keep short channel effects in control. This includes scaling the gate oxide along with the junction depth. As the gate oxide thickness is reduced, minimizing polysilicon depletion effects by increasing the polysilicon doping can provide a larger opportunity to improve transistor performance.

However, depending on the way that the dopant is activated, adding higher doping concentrations to the polysilicon is accompanied by the associated increase in the source/drain junctions and the resulting spread of source drain junctions. The diffusive spread of source drain junctions may result in short channel effects that degrade the performance of transistors.

Thus, there is a need for ways to increase the polysilicon doping without adverse short channel effects that accompany the increased doping in the source/drain junctions.

### BRIEF DESCRIPTION OF THE DRAWINGS

FIG. 1 is a schematic depiction of one embodiment of the present invention; and

FIG. 2 is a schematic depiction of another embodiment of the present invention.

### DETAILED DESCRIPTION

By forming n-type source drain junctions by codoping with carbon or fluorine and relatively high dosages of phosphorous, a transistor may be fabricated with reduced polysilicon gate depletion and high drive currents. Using carbon or fluorine ion implant codoping controls the diffusion of phosphorous in the source and drain regions, reducing the degradation of the short channel performance. The diffusion of phosphorous in the polysilicon gate is unhindered because diffusion through grain boundaries is the primary mechanism.

In other words, while carbon or phosphorus controls the diffusion of phosphorous in single crystalline silicon, it does not unduly limit the diffusion of phosphorous in polysilicon because of the different diffusion mechanisms involved. Thus, surprisingly, the combination of heavy phosphorous doping with carbon or fluorine implants can result in transistors with good polysilicon depletion and high drive currents without degrading short channel effects.

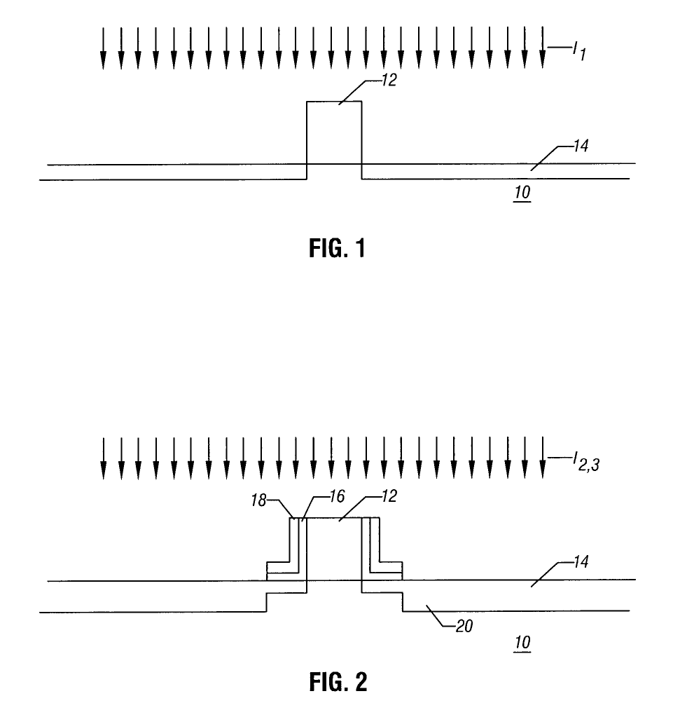

Referring to FIG. 1, a tip or extension implant I1 may be used with a defined polysilicon structure 12 to form the tip or extension region 14 in the semiconductor substrate 10. The tip or extension implant I1 typically involves the use of arsenic.

Thereafter, a sidewall spacer may be formed which, in one embodiment, may be made up of a thinner layer 16, followed by a thicker layer 18. In some embodiments, the layers 16 and 18 may be insulators. The formation of sidewall spacers is well known to those skilled in the art.

Following the formation of sidewall spacers, the deep source drain junction 20 may be formed by implants I2 and I3, which are a relatively high dose phosphorous implant with a carbon or fluorine implant. The implants I2, I3 may be sequential in nature so that the carbon and phosphorous implants need not occur at the same time.

By the term relatively high dosage, it is intended to refer to dosages that are much higher than typical phosphorous doping. The higher phosphorous doping level overcomes any activation issues that may arise due to the use of carbon doping. For example, phosphorous doping on the order of 1E16 atoms per square centimeter or higher, for example at an energy of 15 keV, may be used.

In one advantageous embodiment of the present invention, the ratio of the carbon or fluorine to the phosphorous concentrations in the substrate may be from about 1 to 1 to about 1 to 10. These codoping ratios result in a reduction of short channel effects, an improvement in drive currents, and desirable polysilicon depletion levels in some embodiments.

The term improvement of short channel effect (SCE) refers to the phenomenon that for a given threshold voltage (Vt), a smaller Lg (gate length) can be supported. Codoping high doses of phosphorus with carbon or fluorine can be shown to improve these SCE's. In other words, with phosphorous at a dose of 1E16 atoms per square centimeter and an energy of 15 keV, the same Vt can support a shorter Lg when phosphorus is co-doped with carbon or fluorine. Thus, the addition of carbon or fluorine allows the use of relatively high dosages of phosphorous to improve transistor drive current without unduly compromising the short channel performance.

Increasing the phosphorous dose improves drive current (IDN) through electrical gate oxide thickness reduction arising from polysilicon depletion. Thus, comparing a phosphorous dosage of 1E15 at 15 keV energy to implants of phosphorous at 1E16, shows that greater phosphorus levels generally enable an increase in the drive current through a decrease in the polysilicon depletion layer thickness when the gate is biased in inversion.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
ion implanting carbon or fluorine and an n-type dopant to form a source drain junction.

2. The method of claim 1 including ion implanting carbon or fluorine and phosphorous to form a source drain junction.

3. The method of claim 1 including implanting carbon or fluorine and an n-type dopant so that the ratio of carbon or fluorine to the n-type dopant concentration in the substrate is from about 1 to 1 to about 1 to 10.

4. The method of claim 1 including implanting phosphorous as the n-type dopant at a dosage higher than 1E15 atoms per cubic centimeter.

5. The method of claim 1 including implanting a shallow source drain junction and implanting a deep source drain junction using carbon and an n-type dopant.

6. The method of claim 1 including forming a gate electrode with carbon and n-type impurities.

7. A method comprising:
implanting carbon or fluorine to form a source drain junction; and
implanting phosphorous at a dosage higher than 1E15 atoms per cubic centimeter to form a source drain junction.

8. The method of claim 7 including implanting carbon or fluorine and phosphorous in a doping concentration ratio of from about 1 to 1 to about 1 to 10.

9. The method of claim 7 including implanting phosphorous at a dosage higher than 1E15 atoms per cubic centimeter.

10. The method of claim 7 including implanting carbon or fluorine and phosphorous to form a gate electrode.

11. A method comprising:
implanting carbon or fluorine in a source drain region;
implanting phosphorous in the source drain region; and
implanting a polysilicon structure with carbon and phosphorous.

12. The method of claim 11 including forming a transistor having a carbon or fluorine and phosphorous doped source drain.

13. The method of claim 12 including forming a transistor having a source drain with the ratio of carbon or fluorine to phosphorous atoms being from about 1 to 1 to about 1 to 10.

14. A method comprising:
forming a source drain having carbon or fluorine and phosphorous dopants in a ratio of about 1 to 1 to about 1 to 10.

15. The method of claim 14 including implanting carbon or fluorine to form the source drain.

16. The method of claim 14 including implanting phosphorous to form the source drain.

17. The method of claim 14 including implanting phosphorous at a dosage higher than 1E15 atoms per cubic centimeter.

18. The method of claim 14 including forming a gate electrode with carbon and phosphorous.

19. A semiconductor device comprising:
a carbon or fluorine and n-type dopant doped polysilicon gate; and
a source drain doped at least in part with carbon or fluorine and an n-type dopant.

20. The device of claim 19 wherein said device includes a transistor.

21. The device of claim 19 wherein the ratio of carbon or fluorine to n-type dopant is from about 1 to 1 to about 1 to 10.

22. The device of claim 19 wherein said n-type dopant is phosphorous.

23. The device of claim 19 wherein the dosage of phosphorous in the source drain is higher than 1E15 atoms per cubic centimeter.

24. An integrated circuit comprising:
a gate electrode having carbon or fluorine doping; and
a source and drain having carbon or fluorine and phosphorous doping wherein the ratio of carbon to phosphorous atoms is from about 1 to 1 to about 1 to 10 and the doping concentration of phosphorous is greater than 1E15 atoms per cubic centimeter.

25. The circuit of claim 24 wherein said circuit includes a transistor.

26. The circuit of claim 24 wherein said gate electrode is formed at least in part of polysilicon.
